(19) United States
(12) Patent Application Publication
(10) Pub. No.: US 2018/0026168 A1
(43) Pub. Date: Jan. 25, 2018

(54) LED LIGHT SOURCE WITH DIFFUSER

(71) Applicant: OSRAM SYLVANIA Inc., Wilmington, MA (US)

(72) Inventors: Alan Lenef, Belmont, MA (US); David Hamby, Andover, MA (US); James Avallon, Beverly, MA (US)

(73) Assignee: OSRAM SYLVANIA Inc., Wilmington, MA (US)

(21) Appl. No.: 15/546,909

(22) PCT Filed: Feb. 12, 2016
(86) PCT No.: PCT/US16/17821

§ 371 Date: Jul. 27, 2017

Related U.S. Application Data
(60) Provisional application No. 62/118,302, filed on Feb. 19, 2015.

(51) Int. Cl. H01L 33/60; H01L 33/56; H01L 25/075

(52) U.S. Cl. CPC H01L 33/60; H01L 25/0753; H01L 33/56; H01L 2933/0091

(57) ABSTRACT

There is herein described a light source that homogenizes the light produced by a large area array of forward directed LEDs mounted on highly reflective substrate, while achieving a low-profile form factor and maintaining high efficacy. The LED light source employs a diffuser comprised of two diffusing layers: a low scattering diffusing layer bonded to the LEDs and a high scattering diffusing layer that is bonded to the low scattering diffusing layer. The LED light source achieves good diffuse illumination with a thin diffuser by making use of a light channeling effect between the highly reflective substrate and the high backscattering from the high scattering diffusing layer.

### CROSS REFERENCES TO RELATED APPLICATIONS

The present application is an international application that claims the benefit of U.S. Provisional Application No. 62/118,302 filed Feb. 19, 2015, which is herein incorporated by reference.

### BACKGROUND OF THE INVENTION

Solid-state light sources based on light-emitting diodes (LEDs) offer great potential for high-efficacy lighting with excellent color rendition. However, by their nature, LEDs are nearly point sources that have high-glare if not properly lensed or diffused. In particular, large area light sources based on arrays of LEDs to replace common fluorescent fixtures or other low radiance area light sources often require complex and expensive components to convert the high-radiance LED emission into low glare, large area surface emission. Often, this is done using an edge-lit approach to have a low-profile form factor, but such solutions require expensive higher power LEDs and therefore additional heat-sinking. More detrimental is that optics must be carefully engineered to provide uniform radiance distributions across the entire emitting surface because light sources are confined to the edges. All of these problems ultimately contribute to cost.

To reduce cost, a simpler approach is to fabricate large area light sources from forward directed arrays of LEDs. However, providing homogeneous light emission from such sources is difficult if one also wants to maintain a low-profile form factor. Furthermore, achieving high-efficiency under these constraints is also difficult.

### SUMMARY OF THE INVENTION

It is an object of this invention to obviate the disadvantages of the prior art.

It is another object of the invention to provide a light source that homogenizes the light produced by a large area array of forward directed LEDs mounted on either a flexible or rigid substrate, while achieving a low-profile form factor and maintaining high efficacy.

It is a further object of the invention to provide a more uniform radiance distribution than provided by an un-diffused array of LEDs without incurring large efficiency penalties or requiring large distances between the diffusing layers and LEDs to provide passive light spreading.

In accordance with an aspect of the invention, there is provided a light source that comprises: a reflective substrate with a reflectivity, R_{sub}, greater than 0.90; an array of light-emitting diodes (LEDs) mounted on the reflective substrate, the array having a spacing, d, between adjacent LEDs, the LEDs having a reflectivity, R_{LED}, greater than 0.7 and a width, W_{LED}, less than d/2; a diffuser having a first diffusing layer of height h₁ and a second diffusing layer of height h₂, the first diffusing layer being bonded to the reflective substrate and the second diffusing layer being bonded to the first diffusing layer; and the first diffusing layer containing a plurality of first scattering centers embedded in a first transparent host material and the second diffusing layer containing a plurality of second scattering centers embedded in a second transparent host material, the first and second diffusing layers having a relationship wherein:

γ′_{sc-2}>γ′_{sc-1};

γ′_{sc-1}h₁+γ′_{sc-2}h₂<10; and

(γ_{abs-1}+α₁)h₁(γ_{abs-2}+α₂)h₂<20×10⁻³
where γ′_{sc-1} is the reduced scattering coefficient for the first diffusing layer;
γ′_{sc-2} is the reduced scattering coefficient for the second diffusing layer;
γ_{abs-1} is the absorption coefficient for the first diffusing layer;
γ_{abs-2} is the absorption coefficient for the second diffusing layer;
α₁ is the host absorptivity for the first diffusing layer; and
α₂ is the host absorptivity for the second diffusing layer.

In a preferred embodiment, the light source has the following parameters:
R_{sub} is greater than 0.95;
R_{LED} is greater than 0.8;
R_{LED} is less than d/5;

$$\frac{{h}_{1} + {h}_{2}}{d} \geq \frac{1}{6} ;$$

$${γ}_{sc - 1}^{′} {h}_{1} + {γ}_{sc - 2}^{′} {h}_{2} < 6 ;$$

$$\frac{{h}_{2} {γ}_{sc - 2}^{′}}{{h}_{1} {γ}_{sc - 1}^{′}} > \frac{1}{2} ; and \\ ( {γ}_{abs - 1} + {α}_{1} ) {h}_{1} + ( {γ}_{abs - 2} + {α}_{2} ) {h}_{2} < 5 \times {10}^{- 3} .$$

An LED light source according to the invention achieves good diffuse illumination with a thin diffuser. This is done by making use of a light channeling effect between a highly reflective substrate and high backscattering from the upper diffusing layer. A laterally graded diffusing layer based on scattering may be further used to provide highly uniform near-field distributions. The light source preferably employs non-structured or graded diffusing materials that provide a smooth radiance distribution over the entire emitting surface rather than having a higher glare, pixilated appearance in the on-state. Also, because the light source uses direct illumination from LED arrays rather than edge lighting with LED sources, the overall radiance level does not have droops or high spots over the emitting area. By making use of simple scattering centers and very high-reflectance substrates, losses that occur through multiple reflections and scattering are minimized, keeping overall efficiency high. Efficiency can be further enhanced by embedding LEDs in an optical host material that index matches the LEDs. This increases extraction from the LED compared to LED emission into air. An additional benefit of the invention is that in the off-state, the normally yellow-emitting phosphor used for white light LEDs would be obscured as well as any pixilation features. Finally, the light source in a preferred aspect provides a complete, low profile, light-source and diffuser system that lends itself to cost-effective roll-to-roll processing.

### BRIEF DESCRIPTION OF THE DRAWINGS

FIG. 1 is a schematic illustration showing an embodiment of the invention and direction of the z-axis.

FIGS. 2A and 2B are an illustrations of the geometry of generalized reflection and source boundary conditions for specular and diffuse reflectors, respectively.

FIG. 3 is a plot of relevant scattering and absorption coefficients for rutile TiO₂ embedded in methyl silicone for a 0.005 mass fraction.

FIG. 4 is a plot showing scattering and reduced scattering coefficients for rutile TiO₂ embedded in methyl silicone versus mass fraction at two different wavelengths. Particle sizes are 250±50 nm.

FIG. 5 is a simulation of radiant emittance distribution from single scattering diffusing layer embodiment with LED package (4 mm×4 mm×1 mm).

FIG. 6 is a simulation of radiant emittance distribution from single scattering diffusing layer embodiment with LED die (1 mm×1 mm×1 mm).

FIG. 7 is a simulation of radiant emittance distribution from double scattering diffusing layer embodiment with LED die (1 mm×1 mm×0.5 mm) with γ′_{sc-1}=100 m⁻¹ and γ′_{sc-1}=5000 m⁻¹ (Mass factions: R_{M-1}=0.0043%, R_{M-2}=0.22%).

FIG. 8 is a simulation of radiant emittance distribution from double scattering diffusing layer embodiment with LED die (1 mm×1 mm×0.5 mm) with γ′_{sc-1}=2000 m⁻¹ and γ′_{sc-1}=5000 m⁻¹ (Mass fractions: R_{M-1}=0.088%, R_{M-2}=0.22%).

FIG. 9 is a plot showing typical TiO₂ mass loading distribution for upper layer to increase uniformity.

FIG. 10 is a simulation of radiant emittance distribution from double scattering diffusing layer embodiment with LED die (1 mm×1 mm×0.5 mm), where upper layer is inhomogeneous. Scattering coefficients: γ′_{sc-1}=200 m⁻¹ and γ′_{sc-2}=5000-15000 m⁻¹ (Mass fractions: R_{M-1}=0.0088%, R_{M-2}=0.22-0.65%).

### DETAILED DESCRIPTION OF THE INVENTION

For a better understanding of the present invention, together with other and further objects, advantages and capabilities thereof, reference is made to the following disclosure and appended claims taken in conjunction with the above-described drawings wherein like numerals represent like parts.

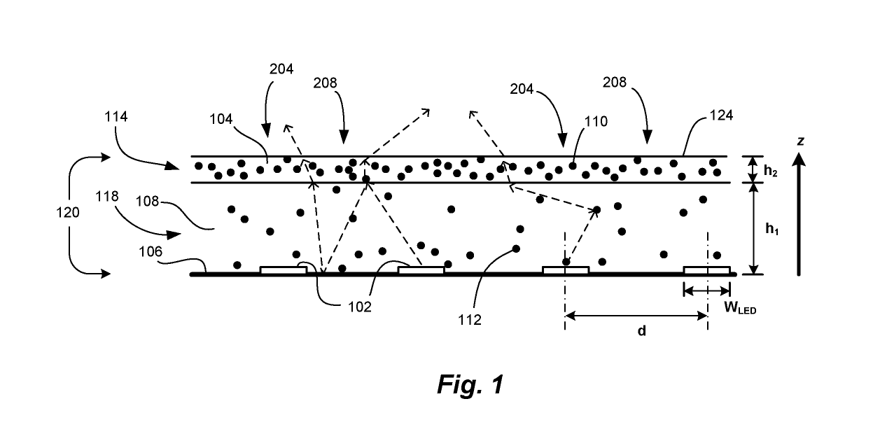

FIG. 1 shows a schematic illustration of an embodiment of the invention. An array of top and/or side emitting LEDs 102 are attached to a high-reflectivity substrate 106 that may be diffuse, specular, or specular-diffuse. LEDs 102 in the array have a width W_{LED} and spacing ‘d’ between them. LED electrical connections (not shown) are made to the substrate 106 by various means including solder, Ag-epoxy, anisotropic conducting adhesives, and other materials known to the art. Conducting traces (not shown) from active devices and power sources can be made on either side of the substrate 106, but must be narrow and have high-reflectivity. Alternatively, lower reflectivity traces on the LED side may be covered with high-reflectivity paint or a second high-reflectivity substrate. The substrate reflectivity on the LED side must be high, preferably above 90% to keep efficacy of the light source high. For white light, LEDs 102 may either be complete packages or (preferably) bare dies coated with a phosphor. Generally, a white LED refers to some combination of a blue LED die and phosphor either in a package or mounted directly on the substrate. However, the invention is not limited to this case and may include any combination of different LED dies, phosphors, and packaging.

Diffuser 120 is made of a transparent host material 104, 108 embedded with scattering centers 110, 112. Diffuser 120 is bonded to the LEDs 102 and substrate 106, making optical interfaces. Diffuser 120 is formed by at least two diffusing layers 114, 118. Lower diffusing layer 118 is a low scattering layer that is directly bonded to the substrate 106 and LEDs 102. Lower diffusing layer 118 has a height (thickness) h₁ and is comprised of transparent host material 108 having embedded scattering centers 112. Upper diffusing layer 114 is a higher scattering layer that is bonded to diffusing layer 118 on one side and whose other side emits into air. Upper diffusing layer 114 has a height (thickness) h₂ and is comprised of transparent host material 104 having embedded scattering centers 110. Preferably, the transparent host material 104 is the same as the transparent host material 108. Scattering centers 110 are also preferably the same as scattering centers 112. The diffusing layers 114, 118 can be formed by a number of methods, but includes embedding strongly scattering particles such as TiO₂ nanoparticles into silicone. Silicones have the benefit of being stable at high temperatures under high blue fluxes while being flexible and having very low optical absorption. The layers can be made by many resin deposition methods known in the art or can be a single layer incorporating an inhomogenous scattering center density in which the upper and lower diffusing layers are delineated by regions of high and low scattering center density, respectively. Inhomogeneous layers may be formed by time-multiplexed or spatial multiplexed dispensing methods. Alternatively, high-resolution printing techniques may be used, similar to use of sparse-to-dense pixilation in newspaper print to simulate photographic gray-scales. The pixilation density must be well below the scattering lengths to achieve smooth variable scattering profiles. Other techniques known in the art may also be used.

The principle of operation is also illustrated in FIG. 1. The highly reflective substrate 106 (preferably diffuse) and strongly scattering upper diffusing layer 114 form an optical channel. Light emitted by the LEDs 102 is partially confined between the upper diffusing layer 114 by backscattering and the reflective substrate 106 by ordinary reflection. In fact, most diffuse reflecting substrates are simply strongly backscattering materials. By confining light to the channel, light rays randomly scatter within the channel, ultimately filling most of the ray positions and ray angles. This, if no losses were present, would provide a region of complete uniform radiance, analogous to the light inside a heated blackbody. Because the upper diffusing layer 114 is partially transmitting, this highly diffuse light then can exit the system into the environment with a nearly Lambertian distribution. Furthermore, the near field light at the surface 124 of the upper diffusing layer 114 would have nearly constant radiance, providing very low glare and a highly uniform appearance.

In practice all materials have some loss, and light that is redirected back into the LEDs is also partly absorbed. An important part of the invention is defining practical scattering and material parameters under which the impact of these losses is not strong while still attaining useful near-field radiance profiles for desired applications. A multilayer diffusing system based on scattering that is outside the desired parameter range will suffer large penalties in efficacy or provide inadequate radiance smoothing.

Referring again to the two-layer approach shown in FIG. 1, the scattering material is applied in two uniform diffusing layers 114, 118 with no lateral or vertical variation in scatter center density within each layer. For sake of illustration, the LEDs 102 are relatively thin and consist of a blue LED die and chip level phosphor conversion layer which is typically silicone embedded with yellow-emitting cerium-activated yttrium aluminum garnet (YAG:Ce) phosphor particles for white light emission. In general, the invention may use nearly any phosphor composition and material, including quantum dots, or combination of these. Converters are also not limited to silicone embedded with phosphor particles, but may include chip level ceramic phosphors, glass phosphors, quantum dots, and other converting systems known in the art.

The substrate 106 can be any highly reflecting material: this includes polished metals such as Ag or Al, dielectric reflectors, possibly combined with metal coatings, scattering particle layers such as BaSO₄, materials embedded with high densities of well-known low loss scatterers such as BaSO₄ or TiO₂ particles. Preferably, the reflective material is primarily a diffuse scatterer, but this is not essential for the invention. For the sake of illustration, the substrate 106 is a BaSO₄-filled polyethylene terephthalate (PET) polymer which has been shown to have reflectances above about 99% throughout most of the visible range. This material has further advantages of being inexpensive and stable and able to support printed flexible electronics.

In one example, the diffusing layers 114, 118 are TiO₂ filled silicone. Because of the high index contrast between TiO₂ (rutile) and silicone, particle loading can be small, minimizing the accumulation of tiny losses that might be incurred from very weak absorption of visible light by TiO₂ particles. Equivalently, the scattering efficiency to absorption per particle for TiO₂ particles of the proper size is expected to be very high. Using silicone for the transparent host material 104, 108 of diffusing layers 114, 118 has the added benefit that it index matches the silicone embedded phosphor on the blue LED dies. This eliminates total internal reflection (TIR) at the converter-diffuser interface which otherwise reduces the extraction efficiency of the light generated by the LED and converter.

The operation of the invention and determination of the appropriate parameter space is demonstrated through simulation. The fundamental method for modeling light scattering problems with incoherent sources is by solving the radiation transport equation. Unfortunately, this is a difficult numerical problem. Descriptions of this method are given in many sources. Alternatively, light scattering can be solved by Monte-Carlo ray tracing which can be done with many commercial software packages. However, this method becomes quite time-consuming and unstable when dealing with high reflectivity surfaces and strong multiple scattering because the ray-tracer must accurately track rays through large numbers of multiple bounces. A third approximate approach, used to model the invention, is the diffusion approximation of the radiation transport equation. This has the disadvantage of being applicable for only high-scattering systems or a system in which radiation does not have a strong angular dependence. However, the scattering parameter range and diffuse scattering regions that apply to the invention are well suited for this approximation. The method has the large advantage that within its range of application, power flows can be accurately calculated and the method can be solved using traditional, fast finite-element methods (FEM). A summary of the method is given herein because it provides a good physical interpretation and guidance for defining the necessary parameter space required by the invention.

For any optical scattering center, important parameters are the scattering and absorption cross-sections σ_{sc} and σ_{abs}, (m²) respectively. When many scattering centers are incorporated into a host material with density nₛ, the relevant quantities are the scattering and absorption coefficients:

γ_{sc}=nₛσ_{sc} (1)

γ_{abs}=nₛσ_{abs} (2)

Another important parameter in scattering is the extinction coefficient γₑₓₜ, which is the fraction of radiation in an incident beam that is removed by scattering and absorption per unit length of the beam:

γₑₓₜ=γ_{sc}+γ_{abs} (3)

The inverse extinction parameter γₑₓₜ⁻¹ is the extinction length. The diffusion approximation described above is valid when the geometric length scales are much bigger than the extinction length.

The basic diffusion approximation is that the radiance L (W/sr/m²) at any point r in the system and direction is given by the first order form:

$$L ( r , \hat{s} ) = \frac{1}{4 π} Φ + \frac{3}{4 π} J \cdot \hat{s} . \qquad ( 4 )$$

The first quantity Φ is called the fluence rate (W/m²) given by angular sum over all directions at each point r.

$$Φ ( r ) ≡ {\int }_{4 π} d Ω L ( r , \hat{s} ) . \qquad ( 5 )$$

The quantity Φ is the isotropic contribution to the radiance in Equation (4). The integral in Equation (5) is over the full sphere (4π-steradians). Physically, if one considers a spherical particle with cross-section a that interacts with the radiation at a point r, then the total power with which the particle interacts is σΦ.

The second term in Equation (4) represents the anisotropic contribution to the radiance at a point r. The quantity J is called the energy flux (W/m²) and is defined by,

$$J ( r ) ≡ {\int }_{4 π} d Ω \hat{s} L ( r , \hat{s} ) . \qquad ( 6 )$$

Physically, if the radiation crosses a surface with normal direction the net irradiance on that surface is given by \hat{n}·J.

With the approximation of Equation (4), the radiation transport equation reduces to a simple diffusion equation given by,

−∇·D∇Φ+γ′_{abs}Φ=∈ (7)

wherein the effect of volume absorption in the host material is included in Equation (7). Here, the parameter D is a diffusion coefficient, has the unusual units of m⁻¹, and is given by

$$D = \frac{1}{3 ( {γ}_{abs}^{′} + {γ}_{sc}^{′} )} . \qquad ( 8 )$$

Note that in the reduced scattering coefficient in Equation (8) γ′_{sc}≠γ_{sc}; rather it has an angular weighting over the scattering angle θ defined by,

$${γ}_{sc}^{′} ≡ ( 1 - g ) {γ}_{sc} \\ g ≡ \frac{1}{{σ}_{sc}} {\int }_{4 π} d Ω cos θ \frac{d {σ}_{sc} ( θ )}{d Ω} . \qquad ( 9 )$$

Here, dσ_{sc}(o)/dΩ is the (azimuthally symmetric) differential scattering cross-section for the scattering centers. The total (primed) absorption coefficient γ′_{abs} represents the total absorption coefficient along a path, including both loss from scattering centers and bulk volume absorption of the host. If the host absorptivity is α (1/m), then the total (primed) absorption coefficient is just,

γ′_{abs}=γ_{abs}+α. (10)

The last quantity in Equation (7), ∈(r), is the power per unit volume (W/m³) emitted by a continuous volume radiation source at r. Once the fluence rate Φ is determined, one can determine the energy flux J, which acts like a diffusion current:

J=−DΠΦ. (11)

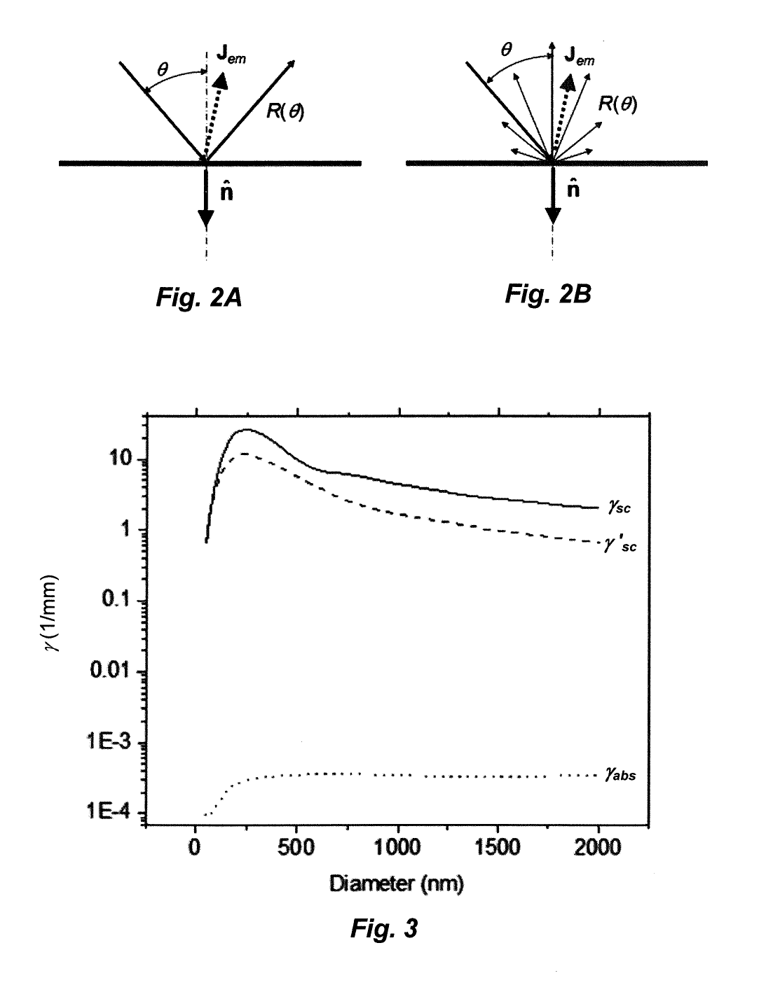

Finally, one needs boundary conditions for reflecting surfaces as shown in FIGS. 2A and 2B. They can be encapsulated by a single formula which is used to describe surfaces having a reflectance R(θ) as a function of angle of incidence θ with respect to the surface normal. The formula applies both for specular reflectors (FIG. 2A) and for reflectors that are purely diffuse (FIG. 2B) (reflected radiation is Lambertian). This can also be generalized to include a surface radiation source characterized by energy flux Jₑₘ. The general mixed boundary condition (Robin boundary condition) for a surface with outward normal \hat{n} is,

$$\hat{n} \cdot J = \frac{2 \hat{n} \cdot {J}_{em}}{1 + {R}_{Φ}} + \frac{1 - {R}_{Φ}}{2 ( 1 + {R}_{J} )} Φ . \qquad ( 12 )$$

In particular, if the source is also Lambertian with radiance Lₑₘ, then the source energy flux from that surface would be Jₑₘ=−\hat{n}πLₑₘ.

The diffusion approximation reflection coefficients in Equation (12) can be shown to be:

$$\begin{matrix}{R}_{Φ} = 2 {\int }_{0}^{π / 2} d θ sin θ cos θ R ( θ ) . & ( 13 ) \\ {R}_{J} = 3 {\int }_{0}^{π / 2} d θ sin θ {cos}^{2} θ R ( θ ) . & ( 14 )\end{matrix}$$

The integration in Equations (13) and (14) are over the angle of incidence θ as indicated in FIGS. 2A and 2B. In the case of reflections from a refractive index discontinuity one simply uses the Fresnel equations for R(θ), averaging over s and p polarizations, and taking R(θ)=1 for angles of incidence greater than the critical angle in the case of the incident ray being in a material of higher index than the transmitted ray.

Finally, transmitted power per unit area or radiant emittance through a specular partially reflecting interface in region 2, \hat{n}·J₂, is just equal to the power incident in region 1, \hat{n}·J₁, provided the interface is lossless. There is also the relationship,

\hat{n}·J₁=\hat{n}·J₂=¼(1−R_{Φ})Φ+¼(1−R_{J})\hat{n}·J₁, (15)

which can be shown by virtue of the boundary condition (12). The full radiance distribution on the transmitted side of the interface requires the other components of J₂ and Φ₂; these can be determined from more complicated formulas.

To evaluate simulations for structures similar to that in FIG. 1, three quantities are important. The first is the diffuser efficiency that is defined by power leaving the diffusing structure over one array cell (or period) to the input LED power in that array cell. Note that this efficiency compares the LED power emitted into the diffusing material which is normally index-matched to the LED, not into air. Thus, experimental efficiencies, based on LED power into in air, may be higher than simulated values because of the increased extraction of light from the LED into a higher index medium. Since the current simulations do not take into account further improvements in extraction efficiency by index matching the LED, simulation efficiencies may under-represent actual efficiencies compared to bare LED arrays emitting directly into air.

Noting the emittance M (W/m²) is defined by,

$$M ( r ) ≡ {\int }_{2 π} d Ω L ( r , \hat{s} ) , \qquad ( 16 )$$

where the 2π in the integration domain refers to integration over the emitting hemisphere, the efficiency η is given by,

$$η = \frac{{P}_{em}}{{P}_{LED}} = \frac{1}{{P}_{LED}} {\int }_{Cell} dA M ( r ) . \qquad ( 17 )$$

Here P_{LED} is the total LED power in a unit cell of the LED array emitted into the host diffusing material. The integration is over one unit cell.

The second quantity is the near-field uniformity. This will be defined as the ratio of the maximum difference in radiant emittance across the surface to the maximum emittance. This is defined by,

$$\frac{Δ M}{M} ≡ \frac{{M}_{max} - {M}_{min}}{{M}_{max}} . \qquad ( 18 )$$

Finally, to quantify the glare reduction (G.R.), one can use the ratio of the LED radiant emittance M_{LED} to the maximum emitted radiant emittance:

$$G . R . ≡ \frac{{M}_{LED}}{{M}_{max}} \qquad ( 19 )$$

### EXAMPLES

Table 1 below summarizes the parameters used in the following embodiments.

TABLE 1
SIMULATION PARAMETERS FOR VARIOUS EXAMPLES

| | | λ | γ′_{sc-1} | γ′_{sc-2} | γ′_{abs} | | | | | | | |
|---|---|---|---|---|---|---|---|---|---|---|---|---|
| FIG. | Example | (nm) | (m⁻¹) | (m⁻¹) | (m⁻¹) | R_{LED} | R_{sub} | R_{Φ} | R_{J} | η | ΔM/M | G.R. |
| 5 | 1 | 570 | 2.38 × 10³ | 2.38 × 10³ | 1.0 | 0.91 | 0.99 | 0.5508 | 0.4128 | 0.674 | 0.77 | 9.4 |
| | | 450 | 2.67 × 10³ | 2.67 × 10³ | 1.0 | 0.91 | 0.99 | 0.5508 | 0.4128 | 0.648 | | |
| 6 | 1 | 570 | 2.38 × 10³ | 2.38 × 10³ | 1.0 | 0.91 | 0.99 | 0.5508 | 0.4128 | 0.770 | 0.81 | 114 |
| 7 | 2 | 570 | 100 | 5 × 10³ | 1.0 | 0.87 | 0.99 | 0.5508 | 0.4128 | 0.953 | 0.14 | 213 |
| | 2 | 570 | 200 | 5 × 10³ | 1.0 | 0.87 | 0.99 | 0.5508 | 0.4128 | 0.941 | 0.19 | 200 |
| | 2 | 570 | 500 | 5 × 10³ | 1.0 | 0.87 | 0.99 | 0.5508 | 0.4128 | 0.908 | 0.35 | 172 |
| | 2 | 570 | 1000 | 5 × 10³ | 1.0 | 0.87 | 0.99 | 0.5508 | 0.4128 | 0.857 | 0.50 | 151 |
| 8 | 2 | 570 | 2000 | 5 × 10³ | 1.0 | 0.87 | 0.99 | 0.5508 | 0.4128 | 0.767 | 0.66 | 136 |
| | 2 | 570 | 5000 | 5 × 10³ | 1.0 | 0.87 | 0.99 | 0.5508 | 0.4128 | 0.571 | 0.75 | 140 |
| 10 | 3 | 570 | 200 | 0.5-1.5 × 10⁴ | 1.0 | 0.87 | 0.99 | 0.5508 | 0.4128 | 0.966 | 0.18 | 213 |

### Example 1—Single Layer Diffuser

In this Example, glare reduction is demonstrated using a single layer configuration. The layers in FIG. 1 are combined into a single homogeneous scattering layer. The host is silicone, preferably a methyl silicone, because of its lower optical absorption. Typical methyl silicone losses are on the order of 0.01 dB/cm at 633 nm and 0.03 dB/cm at 400 nm. This puts a worst case limit on the host absorption coefficient α<0.35 m⁻¹, which would be used in Equation (10). For scattering centers, sub-micron titanium dioxide (TiO₂) particles in the rutile form are excellent scattering centers because of their very high refractive index (˜2.6) and very high transparency in the visible.

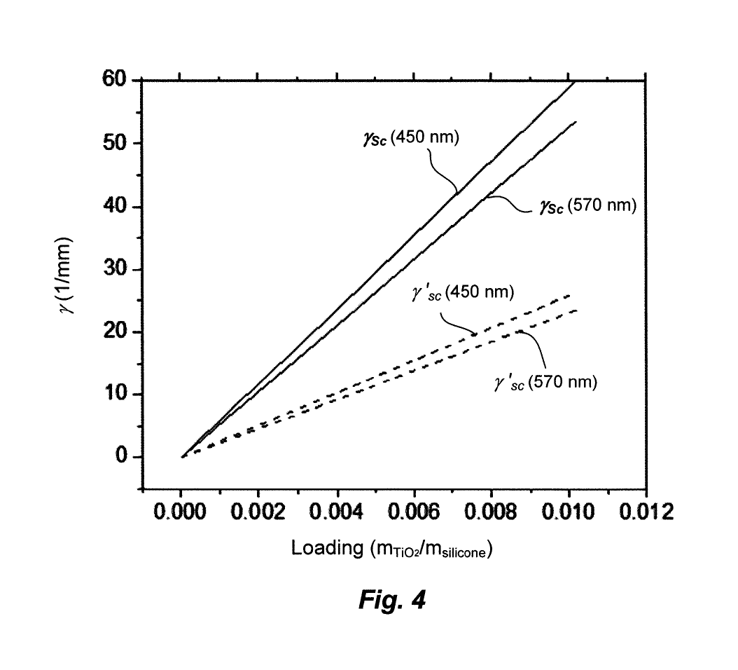

Taking the index of refraction for a typical methyl silicone of 1.43, FIGS. 3 and 4 show plots of various scattering coefficients for TiO₂ particles embedded in silicone. FIG. 3 shows the variation of the scattering coefficients γ′_{sc}, γ′_{sc}, and γ_{abs} versus mean diameter for a fixed mass loading R_{M}=M_{TiO}_{₂}/M_{silicone}=0.005. In FIG. 3, particle diameters were assumed to follow a log-normal distribution with a standard deviation equal to 20% of the mean diameter. Included in the plot is an estimate of absorption coefficient (Mie calculation) for scatterers based on bulk measured absorptivities of rutile TiO₂ for which α_{TiO}_{₂}≈100 m⁻¹. The calculation shows maximum scattering efficiency near diameters of 250 nm. FIG. 4 shows the corresponding variation in scattering and reduced scattering coefficients at yellow (570 nm) and blue (450 nm) wavelengths for 250±50 nm diameter rutile TiO₂ particles versus mass loading. This result is used to determine mass loading for desired scattering behavior in the embodiment.

An experimental version of the one layer scattering diffuser was fabricated on a flexible BaSO₄ filled PET substrate. The reflectance of the substrate material was measured and found to exceed 99% at most visible wavelengths. A 14×14 array of OSRAM Opto Semiconductors 150 mA Duris® white LEDs were mounted on the substrate. The LEDs have an approximate 3 mm×5 mm×1 mm footprint and were spaced approximately 15 mm apart. The bare array produced 1500 lumens with an efficacy of 147 LPW. The substrate with mounted LEDs was then coated with a TiO₂-filled silicone layer of approximately 5 mm in thickness and with a mass TiO₂ loading of 0.1%. The silicone was then cured. The LPW of the array with the scattering layer produced 100 LPW (1050 lumens), giving an approximate efficiency η≈0.68, based on LED luminous fluxes into air for the bare array. Qualitatively, the glare was significantly reduced, although pixilation was quite evident.

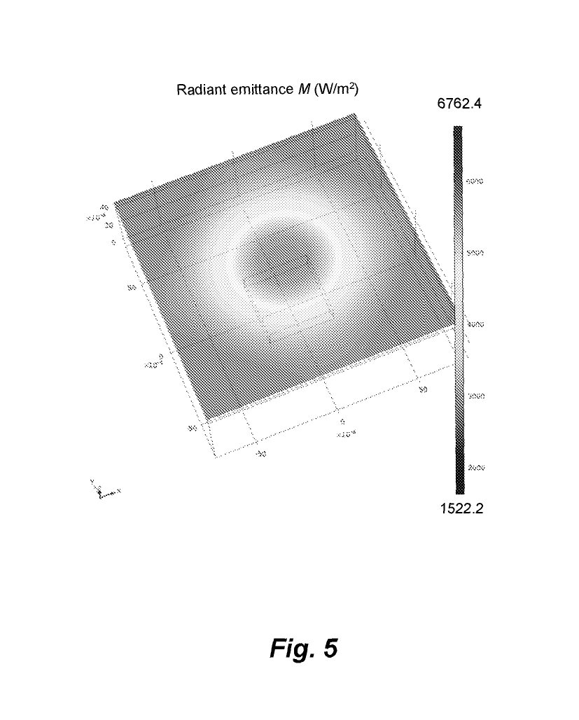

Simulations of the above experimental configuration were made to verify the model and aid in refinement steps. Scattering parameters were determined based on the experimental TiO₂ loading and shown in Table 1. (For this simulation, γ′_{sc-1} was set equal to γ′_{sc-2} to simulate a single diffusing layer.) A value of R_{sub}=0.99 was used to match the experimental value of the filled PET substrate; the net LED reflectance was then adjusted to match the experimental efficiency, neglecting the extraction effects. A value of R_{LED}=0.91 was chosen. Table 1 summarizes the primary parameters used and the calculated performance parameters. In this simulation, LED packages were simulated as top emitting square prisms of width 4.0 mm and height 1.0 mm. The period of the LED array was 15 mm as in the experimental version. FIG. 5 shows the radiant emittance distribution from the emitting surface over one period. In this basic approach, glare is reduced because of some spreading of the LED light distribution, but the overall distribution is highly non-uniform leading to a pixilated near-field distribution as observed experimentally. The efficiencies were calculated for blue and yellow light, with the yellow having η=0.674. The glare reduction was based on 1 W of light emitted by the LED, giving M_{LED}=6.25×10⁴ W/m². The corresponding calculated maximum radiant intensity from the surface was Mₘₐₓ=6.67×10³ W/m², giving a glare reduction G.R.=9.4.

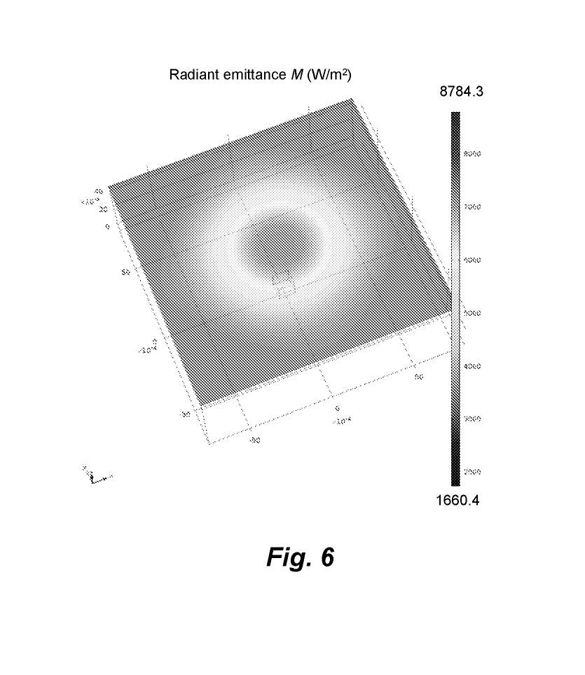

To increase the efficiency, one can use smaller LEDs to reduce the interaction area with the lower reflectance of the LED compared to the very high-reflectance filled PET substrate. In practice this is achieved by using dies with silicone phosphor directly deposited on dies. To focus only on the change of die emitting area, the die dimensions were reduced to 1 mm×1 mm×1 mm. The simulation result is shown in FIG. 6. The efficiency η=0.770 for yellow is clearly improved, but as shown in the figure and Table 1, the non-uniformity has increased and would result in noticeably greater pixilation effect. However, because of the small die, the glare reduction is quite large; G.R.=114.

### Example 2—Two Layer Diffuser

In the second Example, a homogeneous two-layer approach (FIG. 1) in accordance with a preferred embodiment of this invention is used to further reduce glare and increase near-field uniformity. Simulations were made for a similarly thick stack: h₁=4.5 mm and h₂=0.5 mm. In this simulation, the LED thickness was reduced; LEDs (with phosphor) were assumed to be 1 mm×1 mm×0.5 mm. The LED reflectance was also reduced slightly to R_{LED}=0.87 to better match high-quality dies. Table 1 shows the parameter range used; only the scattering coefficient of the lower diffusing layer 118 was changed. The corresponding TiO₂ loadings ranged from 0.0043%-0.22%. For the upper diffusing layer 114 the corresponding TiO₂ loading was approximately 0.22%.

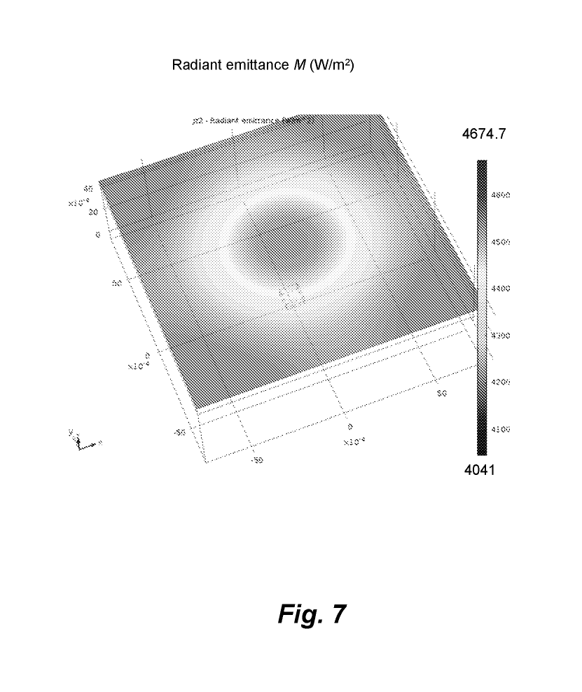

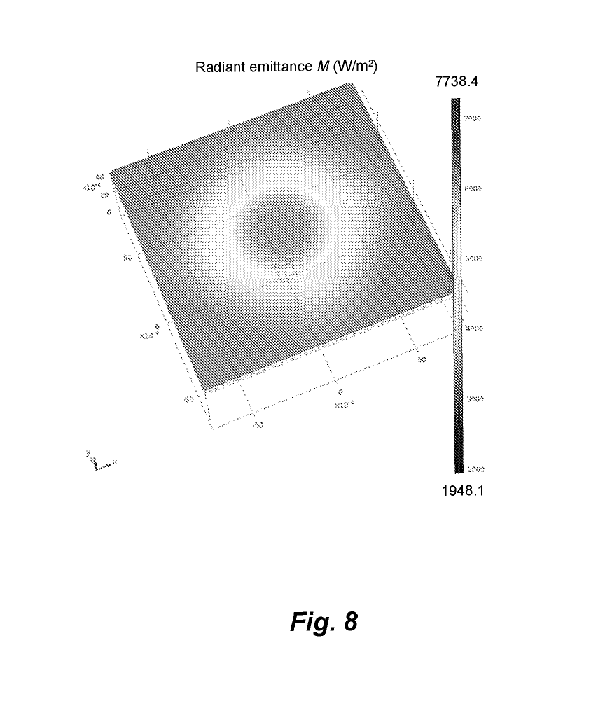

Results show that when the lower diffusing layer 118 is low scattering, efficiencies and uniformity are very good and far better than the single layer approach as shown in FIG. 7 and Table 1. The lowest scattering coefficient for the lower diffusing layer 118 provides the best results for efficiency, uniformity, and glare reduction. Note that at this lowest scattering coefficient value, γ_{sc}h₁=2, so the diffusion approximation maybe suspect, but the multiple scattering within the low diffusing layer keeps the radiation more diffuse in all directions and therefore improves the approximation of Equation (4). FIG. 8 shows the radiant emittance for the case of a much higher scattering coefficient for the lower diffusing layer. Table 1 indicates that efficiencies are now close to the single layer efficiencies and with similar uniformities. The reason that the low scattering low diffusing layer is highly beneficial is that rays can propagate down the channel formed by the substrate and upper layer without being interrupted by additional scattering events or losses incurred by longer optical path lengths. Although, outside the conditions for the diffusion approximation, one would expect that having an inner layer without scattering centers would provide the best performance, although, some spatial structure in the near-field may be expected to occur.

In practice, two layers can be fabricated easily by using two separate TiO₂-loaded silicone applications. After the first application, a partial curing is used to minimize deformation and penetration of scattering particles into the inner layer. After application of the higher loaded layer, the entire resin is cured. Other methods know in the art may also be used.

### Example 3—Two Layer Diffuser

One of the disadvantages of the two-layer configuration is the need for a thicker layer of scattering media. This can lead to excess weight, manufacturing time, higher probability of defects, and expense. To achieve a thinner layer with comparable glare reduction, uniformity, and efficiency, one can employ lateral variations (x-y plane orthogonal to the z axis) in the upper diffusing layer to reduce transmission of light above the LED region (FIG. 1, region 204) while having increased transmission of light away from the LED (FIG. 1, region 208).

A suitable scattering distribution in the upper diffusing layer to accomplish this is a two-dimensional (2D) radial Gaussian profile for the reduced scattering coefficient in the upper layer. We use the following form for simulations over the x-y plane:

γ′_{sc-2}(x,y)=γ′₀+(γₘₐₓ−γ′₀)e^{-(x}^{²}^{+y}^{²}^{)/2σ}^{²} (20)

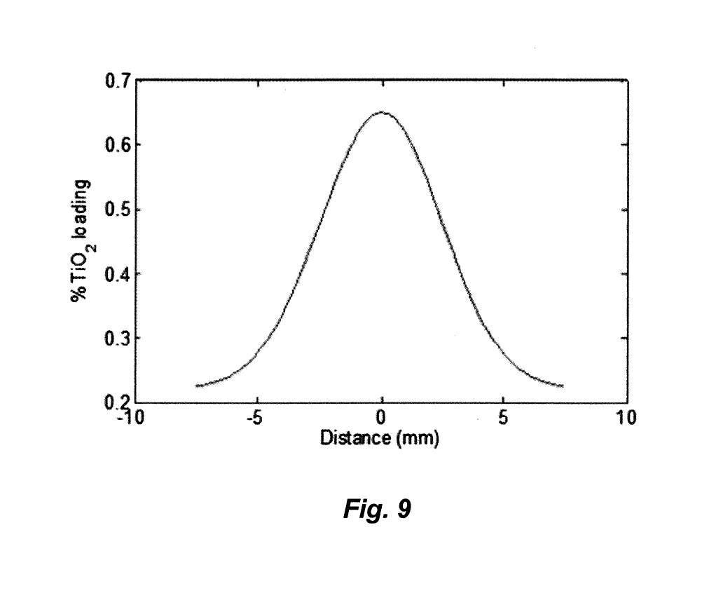

Here, the distribution is determined by minimum and maximum reduced scattering coefficient values, γ′₀ and γ′ₘₐₓ, and a standard deviation of the spatial distribution σ. FIG. 9 shows a typical scattering center mass loading distribution that would achieve the desired transmission variation for flattening the radiant emittance profile of a thin diffuser.

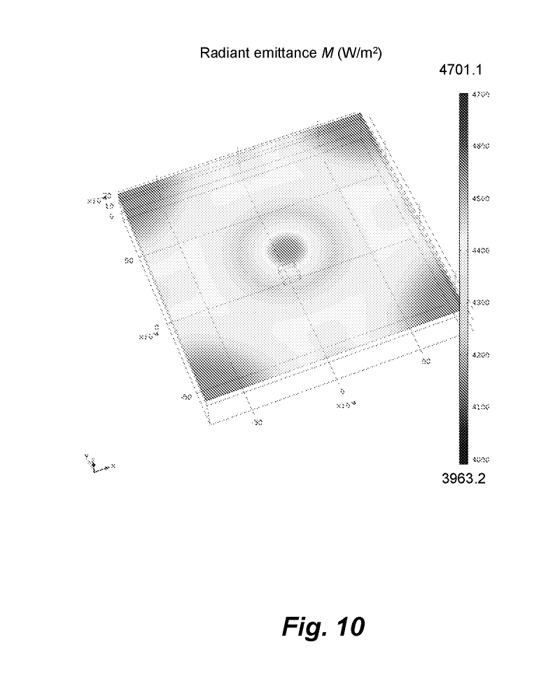

This approach was applied to a thinner 2.5 mm thick diffuser. After a short parameter search, reasonable radiant emittance distributions could be found. One of the best results is shown in FIG. 10 and summarized in Table 1. Not included in Table 1 are the parameters used in Equation (20): γ₀=5×10³ m⁻¹, γₘₐₓ=1.5×10⁴ m⁻¹, and σ=3.5 mm. Radiant emittance varies only 16% over a unit cell, and efficiency is the best calculated among all cases. Surprisingly, efficiency was always high for this thinner diffuser, provided the lower diffusing layer was low scattering; this is in spite of the enhanced back-scattering towards the LED. However good uniformity occurred only for a relatively small parameter range over which the large initial non-uniform radiant emittance could be correctly compensated.

### Example 4

In this Example, parameter ranges are provided over which the invention will provide useful enhancements in glare reduction and near-field uniformity, while having at least usable efficiencies. The ranges are empirically based on simulation results, taking into account theoretical scaling properties. The ranges are by no means absolute and other combinations outside the expected ranges may also provide useful results, depending on application, materials, and geometries.

Substrate reflectivities need to be very high in order to minimize losses for radiation confined between substrate and light channeled in the scattering layer(s). A preferred range of parameters over which the invention is expected to provide a benefit are

$$\begin{matrix}{R}_{sub} > 0.90 & ( 21 ) \\ {R}_{LED} > 0.7 & ( 22 ) \\ {w}_{LED} < \frac{d}{2} & ( 23 ) \\ {γ}_{sc - 1}^{′} {h}_{1} + {γ}_{sc - 2}^{′} {h}_{2} < 10 & ( 24 ) \\ ( {γ}_{abs - 1} + {α}_{1} ) {h}_{1} + ( {γ}_{abs - 2} + {α}_{2} ) {h}_{2} < 20 \times {10}^{- 3} & ( 25 )\end{matrix}$$

Any one parameter which approaches these lower bounds will generally result in low efficiencies. Note that in Equations (21) through (25), the number subscripts refer to the layers and in general may involve more than the two layers indicated.

The following parameter space which keeps efficiencies η near 80% with uniformity ΔM/M near 0.6 is the following:

$$\begin{matrix}{R}_{sub} > 0.95 & ( 26 ) \\ {R}_{LED} > 0.8 & ( 27 ) \\ {w}_{LED} < \frac{d}{5} & ( 28 ) \\ \frac{{h}_{1} + {h}_{2}}{d} \geq \frac{1}{6} & ( 29 ) \\ {γ}_{sc - 1}^{′} {h}_{1} + {γ}_{sc - 2}^{′} {h}_{2} < 6 & ( 30 ) \\ \frac{{h}_{2} {γ}_{sc - 2}^{′}}{{h}_{1} {γ}_{sc - 1}^{′}} > \frac{1}{2} & ( 31 ) \\ ( {γ}_{abs - 1} + {α}_{1} ) {h}_{1} + ( {γ}_{abs - 2} + {α}_{2} ) {h}_{2} < 5 \times {10}^{- 3} & ( 32 )\end{matrix}$$

In this case, one can likely obtain the indicated efficiency and uniformity for most combinations of parameters that satisfy inequalities (26) through (32). Note that these constraints are only approximations; and again parameter values outside these ranges may be found which give comparable efficiencies and uniformities, depending on materials, geometry, and other considerations.

Many variations can be considered which retain the main concepts. One variation on the presented embodiments is to replace the scattering particles by other very low loss large optical cross-section scattering centers. This can include introducing pores, randomly oriented anisotropic grains such as in alumina, second phases, and other light scattering centers.

Another variation is to embed phosphor particles in the host diffusing material rather than direct attachment to the LED dies. In this case, blue LED dies are directly bonded and index matched to a phosphor containing diffusing layer. The embedded phosphor particles can both aid scattering and help provide a lower initial radiance light source, at least for converted light which may further improve near-field uniformity. Such an approach has the additional advantage that conversion takes place at lower light fluxes and therefore will be at a lower temperature. This also helps reduce die temperature. These temperature reductions, combined with larger area of the conversion layer (reduced etendue requirements) can further increase efficiency and extraction from the LED.

Additionally, although the application area of the invention is low cost, flexible, thin area light sources, one can also apply the approach to other higher density light sources as well as inflexible substrates and/or diffusing materials.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A light source, comprising:
a reflective substrate with a reflectivity, R_{sub}, greater than 0.90;
an array of light-emitting diodes (LEDs) mounted on the reflective substrate, the array having a spacing, d, between adjacent LEDs, the LEDs having a reflectivity, R_{LED}, greater than 0.7 and a width, W_{LED}, less than d/2;
a diffuser having a first diffusing layer of height h₁ and a second diffusing layer of height h₂, the first diffusing layer being bonded to the reflective substrate and the second diffusing layer being bonded to the first diffusing layer; and
the first diffusing layer containing a plurality of first scattering centers embedded in a first transparent host material and the second diffusing layer containing a plurality of second scattering centers embedded in a second transparent host material, the first and second diffusing layers having a relationship wherein:
γ′_{sc-2}>γ′_{sc-1};
γ′_{sc-1}h₁+γ′_{sc-2}h₂<10; and
(γ_{abs-1}+α₁)h₁+(γ_{abs-2}+α₂)h₂<20×10⁻³
where γ′_{sc-1} is the reduced scattering coefficient for the first diffusing layer;
γ′_{sc-2} is the reduced scattering coefficient for the second diffusing layer;
γ_{abs-1} is the absorption coefficient for the first diffusing layer;
γ_{abs-2} is the absorption coefficient for the second diffusing layer;
α₁ is the host absorptivity for the first diffusing layer; and
α₂ is the host absorptivity for the second diffusing layer.

2. The light source of claim 1 wherein:
R_{sub} is greater than 0.95;
R_{LED} is greater than 0.8;
W_{LED} is less than d/5;
$$\frac{{h}_{1} + {h}_{2}}{d} \geq \frac{1}{6} ;$$
$${γ}_{sc - 1}^{′} {h}_{1} + {γ}_{sc - 2}^{′} {h}_{2} < 6 ;$$
$$\frac{{h}_{2} {γ}_{sc - 2}^{′}}{{h}_{1} {γ}_{sc - 1}^{′}} > \frac{1}{2} ; and \\ ( {γ}_{abs - 1} + {α}_{1} ) {h}_{1} + ( {γ}_{abs - 2} + {α}_{2} ) {h}_{2} < 5 \times {10}^{- 3} .$$

3. The light source of claim 1 wherein the first and second scattering centers are titanium dioxide (TiO₂) particles.

4. The light source of claim 3 wherein the TiO₂ particles have a particle size distribution of in a range of 250±50 nm.

5. The light source of claim 1 wherein the substrate is a BaSO₄-filled PET polymer.

6. The light source of claim 1 wherein the first and second transparent host materials are a silicone.

7. The light source of claim 1 wherein the first and second diffusing layers are comprised of the same materials and the first and second diffusing layers are defined by regions of low and high scattering center density, respectively.

8. The light source of claim 1 wherein the substrate is a diffuse reflector.

9. The light source of claim 1 wherein the first and second scattering centers are distributed homogeneously within the first and second diffusing layers, respectively.

10. The light source of claim 1 wherein the second diffusing layer has lateral variations of the second scattering centers to reduce transmission of light in regions above the LEDs and increase transmission of light in regions away from the LEDs.

11. The light source of claim 10 wherein the lateral variations have a 2D radial Gaussian profile.
